(19) United States
(12) Patent Application Publication
(10) Pub. No.: US 2019/0332928 A1
(43) Pub. Date: Oct. 31, 2019

(54) SECOND ORDER NEURON FOR MACHINE LEARNING

(71) Applicant: Rensselaer Polytechnic Institute, Troy, NY (US)

(72) Inventors: Ge Wang, Loudonville, NY (US); Wenxiang Cong, Albany, NY (US); Fenglei Fan, Troy, NY (US)

(73) Assignee: Rensselaer Polytechnic Institute, Troy, NY (US)

(21) Appl. No.: 16/394,111

(22) Filed: Apr. 25, 2019

Related U.S. Application Data
(60) Provisional application No. 62/662,235, filed on Apr. 25, 2018.
(60) Provisional application No. 62/837,946, filed on Apr. 24, 2019.

(51) Int. Cl. G06N 3/063; G11C 11/54; G06N 3/08; G06N 20/00

(52) U.S. Cl. CPC G06N 3/063; G06N 20/00; G06N 3/08; G11C 11/54

(57) ABSTRACT

A second order neuron for machine learning is described. The second order neuron includes a first dot product circuitry and a second dot product circuitry. The first dot product circuitry is configured to determine a first dot product of an intermediate vector and an input vector. The intermediate vector corresponds to a product of the input vector and a first weight vector or the input vector and a weight matrix. The second dot product circuitry is configured to determine a second dot product of the input vector and a second weight vector. The input vector, the intermediate vector, the first weight vector and the second weight vector each contain a number, n, elements.

### CROSS REFERENCE TO RELATED APPLICATION(S)

This application claims the benefit of U.S. Provisional Application No. 62/662,235, filed Apr. 25, 2018, and U.S. Provisional Application No. 62/837,946, filed Apr. 24, 2019, which are both incorporated by reference as if disclosed herein in their entirety.

### FIELD

The present disclosure relates to a neuron, in particular to, a second order neuron for machine learning.

### BACKGROUND

In the field of machine learning, artificial neural networks (ANNs), particularly deep neural networks such as convolutional neural networks (CNNs), have achieved success in various types of applications including, but not limited to, classification, unsupervised learning, prediction, image processing, analysis, etc. Generally, ANNs are constructed with artificial neurons of a same type. The artificial neurons generally include two features: (1) an inner (i.e., dot) product between an input vector and a matching vector of trainable parameters and (2) a nonlinear excitation function. These artificial neurons can be interconnected to approximate a general function but the topology of the resulting network is not unique.

### SUMMARY

In some embodiments, an apparatus includes a second order neuron. The second order neuron includes a first dot product circuitry and a second dot product circuitry. The first dot product circuitry is configured to determine a first dot product of an intermediate vector and an input vector. The intermediate vector corresponds to a product of the input vector and a first weight vector or the input vector and a weight matrix. The second dot product circuitry is configured to determine a second dot product of the input vector and a second weight vector. The input vector, the intermediate vector, the first weight vector and the second weight vector each contain a number, n, elements.

In some embodiments of the apparatus, the second order neuron further includes a nonlinear circuitry configured to determine the output of the second order artificial neuron based, at least in part, on the first dot product and based, at least in part, on the second dot product.

In some embodiments of the apparatus, each element of the intermediate vector corresponds to a product of a respective weight of the first weight vector and a respective element of the input vector.

In some embodiments of the apparatus, the intermediate vector corresponds to the product of the weight matrix and the input vector, the weight matrix having dimension n×n.

In some embodiments of the apparatus, the second order neuron further includes a third dot product circuitry, a multiplier circuitry and a summer circuitry. The third dot product circuitry is configured to determine a third dot product of the input vector and a third weight vector. The third weight vector containing the number, n, elements. The multiplier circuitry is configured to multiply the second dot product and the third dot product to yield an intermediate product. The summer circuitry is configured to add the intermediate product and the first dot product to yield an intermediate output. The output of the second order neuron is related to the intermediate output.

In some embodiments of the apparatus, the second order neuron further includes a summer circuitry configured to add the first dot product and the second dot product to yield an intermediate output. The output of the second order neuron is related to the intermediate output.

In some embodiments of the apparatus, the n is equal to two and the second order neuron is configured to implement an exclusive or (XOR) function or a NOR gate. In some embodiments of the apparatus, the second order neuron is configured to classify a plurality of concentric circles. In some embodiments of the apparatus, each weight is determined by training.

In some embodiments of the apparatus, the nonlinear circuitry is configured to implement a sigmoid function.

In some embodiments, a system includes a device and an artificial neural network (ANN). The device includes a processor circuitry, a memory circuitry and an artificial neural network (ANN) management circuitry. The ANN includes a second order neuron. The device is configured to provide an input vector to the ANN. The second order neuron includes a first dot product circuitry and a second dot product circuitry. The first dot product circuitry is configured to determine a first dot product of an intermediate vector and the input vector. The intermediate vector corresponds to a product of the input vector and a first weight vector or the input vector and a weight matrix. The second dot product circuitry is configured to determine a second dot product of the input vector and a second weight vector. The input vector, the intermediate vector, the first weight vector and the second weight vector each contain a number, n, elements.

In some embodiments of the system, the second order neuron further includes a nonlinear circuitry configured to determine the output of the second order artificial neuron based, at least in part, on the first dot product and based, at least in part, on the second dot product.

In some embodiments of the system, each element of the intermediate vector corresponds to a product of a respective weight of the first weight vector and a respective element of the input vector.

In some embodiments of the system, the intermediate vector corresponds to the product of the weight matrix and the input vector, the weight matrix having dimension n×n.

In some embodiments of the system, the second order neuron further includes a third dot product circuitry, a multiplier circuitry and a summer circuitry. The third dot product circuitry is configured to determine a third dot product of the input vector and a third weight vector. The third weight vector containing the number, n, elements. The multiplier circuitry is configured to multiply the second dot product and the third dot product to yield an intermediate product. The summer circuitry is configured to add the intermediate product and the first dot product to yield an intermediate output. The output of the second order neuron is related to the intermediate output.

In some embodiments of the system, the second order neuron further includes a summer circuitry configured to add the first dot product and the second dot product to yield an intermediate output. The output of the second order neuron is related to the intermediate output.

In some embodiments of the system, the n is equal to two and the second order neuron is configured to implement an exclusive or (XOR) function or a NOR gate. In some embodiments of the system, the second order neuron is configured to classify a plurality of concentric circles.

In some embodiments, the system further includes training circuitry configured to determine each weight.

In some embodiments of the system, the nonlinear circuitry is configured to implement a sigmoid function.

### BRIEF DESCRIPTION OF THE DRAWINGS

The drawings show embodiments of the disclosed subject matter for the purpose of illustrating features and advantages of the disclosed subject matter. However, it should be understood that the present application is not limited to the precise arrangements and instrumentalities shown in the drawings, wherein:

FIG. 1 illustrates a functional block diagram of a second order neuron for machine learning consistent with several embodiments of the present disclosure;

FIG. 2 illustrates a sketch of one example second order neuron for machine learning consistent with one embodiment of the present disclosure;

FIG. 3 illustrates a functional block diagram of a system that includes a second order neuron for machine learning consistent with one embodiment of the present disclosure;

FIG. 4 is an example flowchart of machine learning operations consistent with several embodiments of the present disclosure; and

FIGS. 5 through 8 are plots illustrating a functional value at each point in an input domain for a two input example second order neuron configured to implement XOR logic, an XOR-like function, a NOR-like function and a concentric ring classifier, respectively.

### DETAILED DESCRIPTION

A model of single neurons (also known as perceptrons) has been applied to solve linearly separable problems. For linearly inseparable tasks, a plurality of layers of a plurality of single neurons may be used to perform multi-scale nonlinear analysis. In other words, such single neurons may be configured to perform linear classification individually and their linear functionality may be enhanced by connected a plurality of such single neurons into an artificial organism.

A single neuron may be configured to receive a plurality of inputs: x₀, x₁, x₂, . . . , xₙ, where x₁, x₂, . . . , xₙ are n elements of a size n input vector and x₀ may correspond to a bias term. As used herein, “vector” corresponds to a one-dimensional array, e.g., 1× n, an n element vector corresponds to an n element array. The single neuron may be configured to generate an intermediate function f(x) as:

$$f ( x ) = {\sum }_{i = 1}^{n} {w}_{i} {x}_{i} + b \qquad ( 1 )$$

where wᵢ, i=1, 2, . . . , n are trainable parameters (i.e., weights), b=w₀ and x₀=1. In this example, b may correspond to a bias that is determined during training and is fixed during operation. It may be appreciated that the sum over i corresponds to the inner (i.e., dot) product of the input vector and a vector of trainable weights. The intermediate function may then be input to a nonlinear function g(f) to produce an output y=g(f(x)). In one nonlimiting example, the nonlinear function may be a sigmoid. In another nonlimiting example, the nonlinear function may correspond to a rectified linear unit (ReLU). A single neuron may separate (i.e., classify) two sets of inputs that are linearly separable. Classifying linearly inseparable groups of inputs using single neuron(s) may result in classification errors.

Generally, the present disclosure relates to a second order neuron for machine learning. The second order neuron is configured to implement a second order function of an input vector, i.e., is configured to include a multiplicative product of elements of the input vector. As used herein, “product” corresponds to a multiplicative product. A second order neuron, consistent with the present disclosure, is configured to implement a quadratic function of an input vector that includes n elements. Generally, the second order neuron may be configured to determine a first dot product of an intermediate vector and an input vector. The intermediate vector may correspond to a product of the input vector and a first weight vector or a product of the input vector and a matrix of weights (“weight matrix”). As used herein, a matrix corresponds to a two-dimensional array, e.g., n×n. As used herein, weights may correspond to structural parameters. Structural parameters may further include bias values, e.g., offsets.

The input vector, the intermediate vector and the first weight vector each have size, n, i.e., contain n elements. The second order neuron may be further configured to determine a second dot product of the input vector and a second weight vector containing n elements. The second order neuron may be further configured to determine an output of the second order neuron based, at least in part, on the first dot product and based, at least in part, on the second dot product. For example, an intermediate output may be input to a nonlinear function circuitry and an output of the nonlinear function circuitry may then correspond to the output of the second order neuron.

As used herein, “second order neuron” corresponds to “second order artificial neuron”. For ease of description, in the following, an example second order artificial neuron is referred to as “example second order neuron” and a general second order artificial neuron is referred to as “general second order neuron”.

The intermediate output of the general second order neuron may be described mathematically as:

$$f ( \vec{x} ) = {{\sum }_{i , j = 1 , i \geq j}}^{n} {a}_{ij} {x}_{i} {x}_{j} + {\sum }_{k = 1}^{n} {b}_{k} {x}_{k} + c \qquad ( 2 )$$

where aᵢⱼ and bₖ are weights; xᵢ, xⱼ, xₖ are elements of an input vector and c is a bias term. The first summing term may correspond to a dot product of an intermediate vector and the input vector, x₁, i=1, 2, . . . , n, with the intermediate vector corresponding to a product of a weight matrix (aᵢⱼ, i=1, 2, . . . , n; j=1, 2, . . . , n and i≥j) and the input vector. In one nonlimiting example, the weight matrix may be a lower triangular matrix. The second summing term corresponds to the second dot product of the input vector and a second weight vector (bₖ, k=1, 2, . . . , n). The intermediate function may then correspond to a sum of the first dot product and the second dot product (including the bias term).

The intermediate output of the example second order neuron may be described mathematically as:

$$f ( x ) = ( {{\sum }_{i = 1}}^{n} {w}_{ir} {x}_{i} + {b}_{1} ) ( {\sum }_{i = 1}^{n} {w}_{ig} {x}_{i} + {b}_{2} ) + {\sum }_{i = 1}^{n} {w}_{ib} {x}_{i}^{2} + c \qquad ( 3 )$$

where wᵢᵣ, w_{ig}, w_{ib} (i=1, 2, . . . , n) are trainable weights, xᵢ (i=1, 2, . . . , n), are elements of the input vector and b₁, b₂ and c are bias terms (e.g., b₁=w₀ᵣx₀, b₂=w_{0g}x₀, c=w_{0b}x₀², x₀=1). The third summing term (that sums w_{ib}xᵢ²) corresponds to a dot product of an intermediate vector and the input vector with the intermediate vector a product of the input vector (x₁, i=1, 2, . . . , n) and the first weight vector (w_{ib}, i=1, 2, . . . , n). The product of the input vector and the first weight vector may be performed element by element so that element i of the intermediate vector corresponds to the product of element i of the input vector and element i of the first weight vector (i.e., w_{ib}xᵢ). The first and second parenthetical terms correspond to the second dot product of the input vector and a second weight vector (wᵢᵣ, i=1, 2, . . . , n) and a third dot product of the input vector and a third weight vector (w_{ig}, i=1, 2, . . . , n). The second dot product and the third dot product may then be multiplied to yield an intermediate product. The intermediate output may then correspond to a sum of the intermediate product and the first dot product.

The intermediate output of the second order neuron may then be provided to a nonlinear function. In one nonlimiting example, the nonlinear function may correspond to a sigmoid function. The sigmoid function may be described as:

$$σ ( f ( x ) ) = \frac{1}{1 + exp ( - β f ( x ) )} \qquad ( 4 )$$

Thus, a second order neuron may be configured to receive an input vector and to determine an intermediate output that corresponds to a quadratic function of the input vector and a plurality of trainable weights. The intermediate output may then be provided to a nonlinear function circuitry configured to determine the second order neuron output.

In one nonlimiting example, the example neuron may be configured, with a two element input vector, to model linearly inseparable functions and/or classify linearly inseparable patterns. Linearly inseparable functions and/or patterns may include, but are not limited to, exclusive-OR (“XOR”) functions, XOR-like patterns, NOR functions, NOR-like patterns, concentric rings, fuzzy logic, etc.

Generally, the present disclosure relates to a second order artificial neuron. The second order artificial neuron includes a first dot product circuitry and a second dot product circuitry. The first dot product circuitry is configured to determine a first dot product of an intermediate vector and an input vector. In one nonlimiting example, the intermediate vector corresponds to a product of the input vector and a first weight vector. In another nonlimiting example, the intermediate vector corresponds to a product of the input vector and a weight matrix. The second dot product circuitry is configured to determine a second dot product of the input vector and a second weight vector. The input vector, the intermediate vector, the first weight vector and the second weight vector each contain a number, n, elements. The second order artificial neuron may further include a nonlinear circuitry configured to determine the output of the second order artificial neuron based, at least in part, on the first dot product and based, at least in part, on the second dot product.

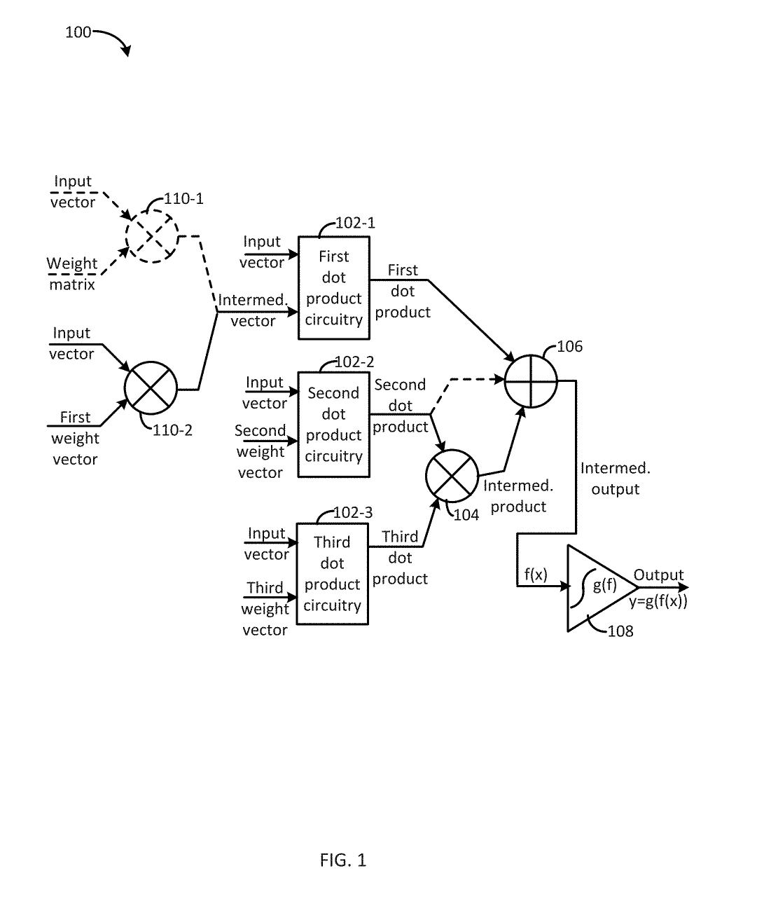

FIG. 1 illustrates a functional block diagram 100 of a second order neuron for machine learning consistent with several embodiments of the present disclosure. Second order neuron 100 includes a first dot product circuitry 102-1, a second dot product circuitry 102-2, a summer circuitry 106 and a nonlinear circuitry 108. In some embodiments, second order neuron 100 may include an intermediate multiplier circuitry 110-1. In some embodiments, second order neuron 100 may include first multiplier circuitry 110-2, a third dot product circuitry 102-3 and a multiplier circuitry 104.

Second order neuron 100 is configured to receive an input vector that includes a number, n, elements. Second order neuron 100 may be further configured to receive a first weight vector, a second weight vector, and/or a third weight vector. Each weight vector may include the number, n, weights. In some embodiments, second order neuron 100 may be configured to receive a weight matrix having dimension n×n. In one nonlimiting example, the weight matrix may be a lower triangular matrix. The weights of the weight vectors and/or the weight matrix may be trainable, i.e., may be determined during training, as described herein.

Second order neuron 100 is configured to determine an intermediate output f(x). The intermediate output may then be provided to nonlinear circuitry 108 that is configured to implement a nonlinear function g(f). An output g(f(x)) of the nonlinear circuitry 108 may then correspond to an output, y, of the second order neuron.

First dot product circuitry 102-1 is configured to receive the input vector and an intermediate vector and to determine a first dot product based, at least in part, on the input vector and based, at least in part, on the intermediate vector. Second dot product circuitry 102-2 is configured to receive the input vector and a second weight vector and to determine a second dot product based, at least in part, on the input vector and based, at least in part, on the second weight vector. Summer circuitry 106 is configured to sum the first dot product and the second dot product or the intermediate product to yield an intermediate output. Nonlinear circuitry 108 is configured to receive the intermediate output and to determine the second order neuron output based, at least in part, on the intermediate output. In one nonlimiting example, nonlinear circuitry 108 may be configured to implement a sigmoid function. In another nonlimiting example, nonlinear circuitry 108 may be configured to implement a rectified linear unit (ReLU).

In an embodiment, second order neuron 100 may correspond to a general second order artificial neuron, as described herein. The general second order neuron may include intermediate multiplier circuitry 110-1, first dot product circuitry 102-1, second dot product circuitry 102-2, summer circuitry 106 and nonlinear circuitry 108. In another embodiment, second order neuron 100 may correspond to an example second order artificial neuron, as described herein. The example second order neuron may include first multiplier circuitry 110-2, first dot product circuitry 102-1, second dot product circuitry 102-2, third dot product circuitry 102-3, multiplier circuitry 104, summer circuitry 106 and nonlinear circuitry 108.

For the general second order neuron, the intermediate vector corresponds to an output of intermediate multiplier circuitry 110-1. Intermediate multiplier circuitry 110-1 is configured to receive the input vector and a weight matrix. According to Equation (Eq.) (2), the weight matrix includes elements aᵢⱼ, where i=1, 2, . . . , n; j=1, 2, . . . , n; and i≥j. Intermediate multiplier circuitry 110-1 may then be configured to determine the corresponding intermediate vector. For example, intermediate multiplier circuitry 110-1 may be configured to multiply the weight matrix by the input vector to yield the intermediate vector. First dot product circuitry 102-1 may then be configured to determine the first dot product of the input vector and the intermediate vector. The first dot product may then correspond to the first term of Eq. (2). Continuing with the general second order neuron, the summer circuitry 106 is configured to receive the first dot product from the first dot product circuitry 102-1 and the second dot product from the second dot product circuitry 102-2. The second dot product corresponds to the dot product of the input vector and the second weight vector. The summer circuitry 106 is configured to add the first dot product and the second dot product to yield the intermediate output.

For the example second order neuron, the first multiplier circuitry 110-2 is configured to receive the input vector and a first weight vector. The first multiplier circuitry 110-2 may then be configured to perform an element by element multiplication to yield the intermediate vector. In one nonlimiting example, each element of the first weight vector may be multiplied by a corresponding element of the input vector. In other words, for vector index, j, in the range of 1 to n, a j^{th} element of the first weight vector may be multiplied by a j^{th} element of the input vector. Thus, each element of the intermediate vector may correspond to an element multiplication of the first weight vector and the input vector.

Continuing with the example second order neuron, first dot product circuitry 102-1 is configured to receive the input vector and the intermediate vector from the first multiplier circuitry 110-2 and to determine the first dot product. The first dot product corresponds to the dot product of the input vector and the intermediate vector. Second dot product circuitry 102-2 is configured to receive the input vector and the second weight vector and to determine a corresponding second dot product. The second dot product corresponds to the dot product of the input vector and the second weight vector. Third dot product circuitry 102-3 is configured to receive the input vector and a third weight vector and to determine a third dot product. The third dot product corresponds to the dot product of the input vector and the third weight vector. Multiplier circuitry 104 is configured to receive the second dot product and the third dot product and to multiply the second dot product and the third dot product to yield an intermediate product. Summer circuitry 106 is configured to receive the first dot product and the intermediate product and to add to the first dot product and the intermediate product to yield the intermediate output.

Thus, a second order neuron may be implemented using multiplier circuitry, summer circuitry and dot product circuitry. It may be appreciated that a dot product function may be implemented by multiplier circuitry and summer circuitry.

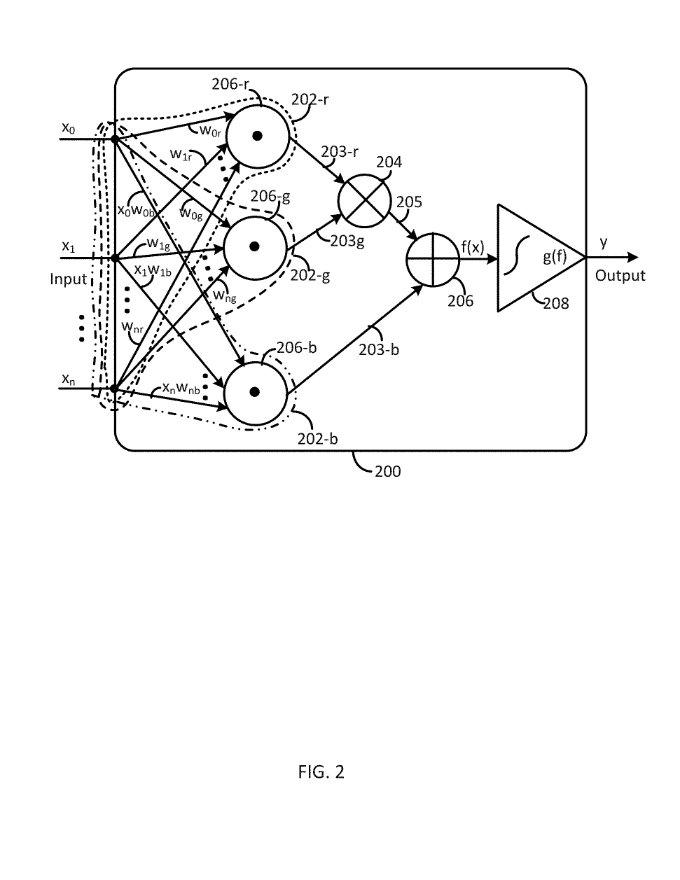

FIG. 2 illustrates a sketch 200 of one example second order artificial neuron for machine learning consistent with one embodiment of the present disclosure. Example second order neuron 200 is one example of second order neuron 100 of FIG. 1. Example second order neuron 200 includes three inner (i.e., dot) product circuitries 202-r, 202-g, 202-b, a multiplier circuitry 204, a summing (i.e., summer) circuitry 206 and a nonlinear excitation circuitry 108. Example second order neuron 200 is configured to receive an input vector that includes a plurality of input elements x₁, x₂, . . . , xₙ. Each input element has a corresponding input value. Example second order neuron 200 is further configured to receive an input, x₀, that may be related to a bias value. Example second order neuron 200 is configured to implement Eq. (3) to yield intermediate output f(x).

Each inner product circuitry 202-r, 202-g, 202-b includes a respective summing circuitry 206-r, 206-g, 206-b and a plurality of multiplier circuitries indicated by lines with arrows. Each inner product circuitry 202-r, 202-g, 202-b is configured to receive the input vector and to determine a dot product of the input vector and a weight vector or intermediate vector. Each weight vector includes n weight elements and the intermediate vector includes n intermediate elements. Each multiplier circuitry is represented by a line labeled with its corresponding weight element value or intermediate element value.

First inner product circuitry 202-b includes n multiplier circuitries with respective intermediate element values x₀w_{0b}, x₁w_{1b}, . . . , xₙw_{nb}. Second inner product circuitry 202-r includes n multiplier circuitries with respective weight element values w₀ᵣ, w₁ᵣ, . . . , wₙᵣ. Third inner product circuitry 202-g includes n multiplier circuitries with respective weight element values w_{0g}, w_{1g}, . . . , w_{ng}.

Thus, the first summing circuitry 206-b is configured to receive intermediate input values w_{0b}x₀², w_{1b}x₁², . . . , w_{nb}xₙ²; second summing circuitry 206-r is configured to receive weighted input values w₀ᵣx₀, w₁ᵣx₁, . . . , wₙᵣxₙ and the third summing circuitry 206-g is configured to receive weighted input values, w_{0g}x₀, w_{1g}x₁, . . . , w_{ng}xₙ and. Each summing circuitry is then configured to determine a respective sum of the weighted or intermediate input values, i.e., a respective dot product of the input vector and the respective weight or intermediate vector.

Multiplier circuitry 204 is configured to receive a second dot product 203-r from the second dot product circuitry 202-r and a third dot product 203-g from the third dot product circuitry 202-g. Multiplier circuitry 204 is configured to multiply the second dot product and the third dot product to yield an intermediate product 205. Summer circuitry 206 is configured to receive the intermediate product from multiplier circuitry 204 and a first dot product 203-b from first dot product circuitry 202-b. Summer circuitry 206 is configured to add the intermediate product and the first dot product to yield an intermediate output, f(x). Nonlinear excitation circuitry 208 is configured to receive the intermediate output and to determine an output, y, of the example second order artificial neuron 200.

Thus, example second order neuron 200 is one example second order neuron configured to implement Eq. (3).

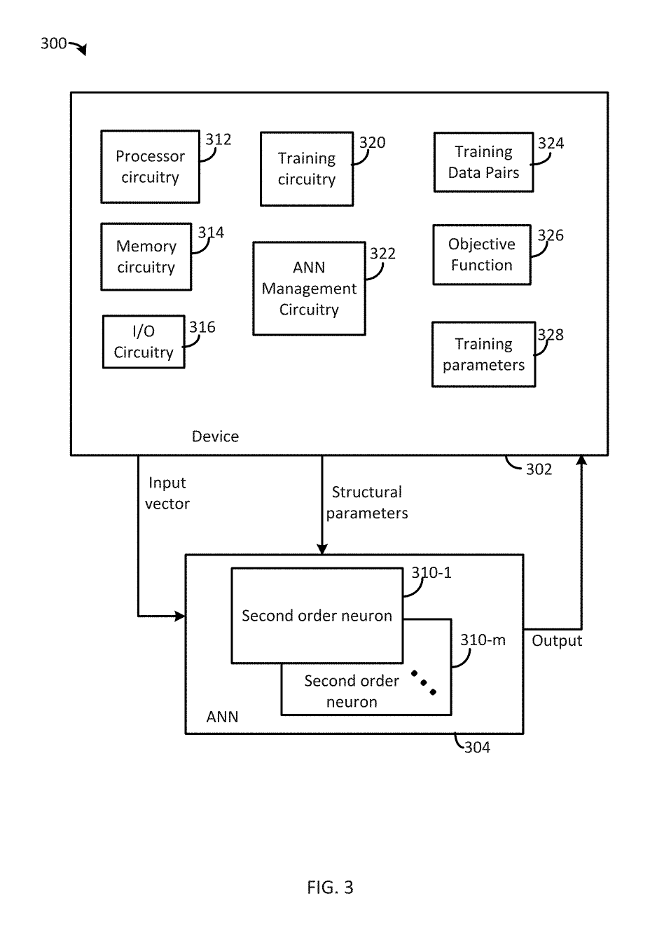

FIG. 3 illustrates a functional block diagram 300 of a system that includes a second order neuron for machine learning consistent with one embodiment of the present disclosure. System 300 includes a device 302 and an artificial neural network (ANN) 304. ANN 304 may be coupled to or included in device 302. The ANN 304 includes one or more second order neurons 310-1, . . . , 310-m. In one nonlimiting example, each second order neuron, e.g., 310-1, may correspond to the general second order neuron, as described herein. In another nonlimiting example, each second order neuron 310-1 may correspond to the example second order neuron, as described herein. System 300 and device 302 may be utilized to train ANN 304 and/or device 302 may utilize ANN 304 to perform one or more operations, after training. The operations may include, but are not limited to, logic functions (e.g., XOR, NOR, fuzzy logic, etc.), classification, etc.

Device 302 includes processor circuitry 312, memory circuitry 314 and input/output (I/O) circuitry 316. Device 302 may further include training circuitry 320, ANN management circuitry 322, training data pairs 324, an objective function 326 and/or training parameters 328. Processor circuitry 312 may be configured to perform operations of device 302 and/or ANN 304. Memory circuitry 314 may be configured to store one or more of training data pairs 324, objective function 326 and objective function associated parameters (if any) and/or training parameters 328.

Training circuitry 320 may be configured to manage training operations of ANN 304, as will be described in more detail below. ANN management circuitry 322 may be configured to manage operation of device 302 and/or ANN 304.

Device 302 may be configured to provide an input vector to ANN 304 and to receive a corresponding output from ANN 304. Device 302 may be further configured to provide structural parameters including weights (e.g., weight vectors and/or a weight matrix) and/or bias values to ANN 304. During training, training circuitry 320 may be configured to provide a training input vector to ANN 304 and to capture a corresponding actual output. Training data pairs 324 may thus include a plurality of pairs of training input vectors and corresponding target outputs. Training circuitry 320 may be configured to compare the actual output with a corresponding target output by evaluating objective function 326. Training circuitry 320 may be further configured to adjust one or more weights to reduce and/or minimize an error associated with objective function 326. Training parameters 328 may include, but are not limited to, an error threshold and/or an epoch threshold. In one nonlimiting example, a gradient descent method may be utilized during training.

In one nonlimiting example, an example second order neuron configured to implement Eq. (3), e.g., example second order neuron 200 of FIG. 2, may be trained. In this example, nonlinear circuitry 208 may be configured to implement a sigmoid function, e.g., Eq. (4) with β set equal to 1. The following may be best understood when considering FIG. 2 in combination with FIG. 3.

A training data set, i.e., training data pairs 324, may include a number, m, samples, i.e., training data pairs X^{k}, y^{k}, k=1, 2, . . . , m, where X^{k}=(x₁^{k}, x₂^{k} . . . , xₙ^{k}) corresponds to the k^{th} input vector and y^{k} is the corresponding k^{th} target output of the training data set. The output of the example second order neuron may then be written as:

$$\begin{matrix}h ( {X}^{k} , {w}_{r} , {w}_{g} , {w}_{b} , {b}_{1} , {b}_{2} ) = σ ( f ( x ) ) \\ = σ ( \begin{matrix}( {\sum }_{i = 1}^{n} {w}_{ir} {x}_{i}^{k} + {b}_{1} ) ( {\sum }_{i = 1}^{n} {w}_{ig} {x}_{i}^{k} + {b}_{2} ) + \\ {\sum }_{i = 1}^{n} {w}_{ib} {( {x}_{i}^{k} )}^{2} + c\end{matrix} )\end{matrix} \qquad ( 5 )$$

An error function may then be defined as:

$$E ( \vec{{w}_{r}} , \vec{{w}_{g}} , \vec{{w}_{b}} , {b}_{1} , {b}_{2} ) = \frac{1}{2} {\sum }_{k = 1}^{m} {( h ( {X}^{k} , {w}_{r} , {w}_{g} , {w}_{b} , {b}_{1} , {b}_{2} ) - {y}^{k} )}^{2} \qquad ( 6 )$$

It may be appreciated that the error function (Eq. (6)) depends, at least in part, on the structural parameters (i.e., weights): \vec{wᵣ}, \vec{w_{g}}, \vec{w_{b}}, b₁, b₂ and c, where \vec{wᵣ}=(w₁ᵣ, w₂ᵣ, . . . wₙᵣ), \vec{w_{g}}=(w_{1g}, w_{2g}, . . . , w_{ng}) and \vec{w_{b}}=(w_{1b}, w_{2b}, . . . w_{nb}). Training, i.e., optimization, is configured to determine optimal parameters (e.g., weights) that minimize an objective function. In one nonlimiting example, gradient descent may be used, with an appropriate initial guess, to determine and/or identify the optimal parameters. During training, \vec{wᵣ}, \vec{w_{g}}, \vec{w_{b}}, b₁, b₂ and c may be iteratively updated in the form of:

$$α = α - η \cdot \frac{\partial E}{\partial α } \qquad ( 7 )$$

where α corresponds to a generic variable of the objective function and η, the step size, is set between zero and one for the optimization. The gradient of the objective function for any sample may then be written as:

$$\begin{matrix}\frac{\partial E}{\partial {w}_{ir}} = ( h ( \vec{{x}_{ι}} ) - {y}_{i} ) \frac{\partial σ}{\partial x} {x}_{i} ( {\sum }_{i = 1}^{n} {w}_{ig} {x}_{i} + {b}_{2} ) & ( 8 a ) \\ \frac{\partial E}{\partial {w}_{ig}} = ( h ( \vec{{x}_{ι}} ) - {y}_{i} ) \frac{\partial σ}{\partial x} {x}_{i} ( {\sum }_{i = 1}^{n} {w}_{ir} {x}_{i} + {b}_{1} ) & ( 8 b ) \\ \frac{\partial E}{\partial {w}_{ib}} = 2 ( h ( \vec{{x}_{ι}} ) - {y}_{i} ) \frac{\partial σ}{\partial x} {w}_{ib} {x}_{i} & ( 8 c ) \\ \frac{\partial E}{\partial {b}_{1}} = ( h ( \vec{{x}_{ι}} ) - {y}_{i} ) \frac{\partial σ}{\partial x} ( {\sum }_{i = 1}^{n} {w}_{ig} {x}_{i} + {b}_{2} ) & ( 8 d ) \\ \frac{\partial E}{\partial {b}_{2}} = ( h ( \vec{{x}_{ι}} ) - {y}_{i} ) \frac{\partial σ}{\partial x} ( {\sum }_{i = 1}^{n} {w}_{ir} {x}_{i} + {b}_{1} ) & ( 8 e ) \\ \frac{\partial E}{\partial c} = ( h ( \vec{{x}_{ι}} ) - {y}_{i} ) \frac{\partial σ}{\partial x} & ( 8 f )\end{matrix}$$

Training may be iterative and may end when an error is less than or equal to an error threshold or a number of training epochs is at or above an epoch threshold.

In another nonlimiting example, for the general second order neuron (Eq. (2)), a training data set may include {\vec{x}ₚ} and {yₚ}. The parameters {aᵢⱼ}, {bₖ} and c may be updated using a gradient descent technique. The gradient of the objective function for any sample may then be written as:

$$\begin{matrix}\frac{\partial E}{\partial {a}_{ij}} = ( h ( \vec{{x}_{p}} ) - {y}_{p} ) \frac{\partial σ}{\partial x} {x}_{i} {x}_{j} & ( 9 a ) \\ \frac{\partial E}{\partial {b}_{k}} = ( h ( \vec{{x}_{p}} ) - {y}_{p} ) \frac{\partial σ}{\partial x} {x}_{k} & ( 9 b ) \\ \frac{\partial E}{\partial c} = ( h ( \vec{{x}_{p}} ) - {y}_{p} ) \frac{\partial σ}{\partial x} & ( 9 c )\end{matrix}$$

Thus, a second order neuron consistent with the present disclosure may be trained using a gradient descent technique.

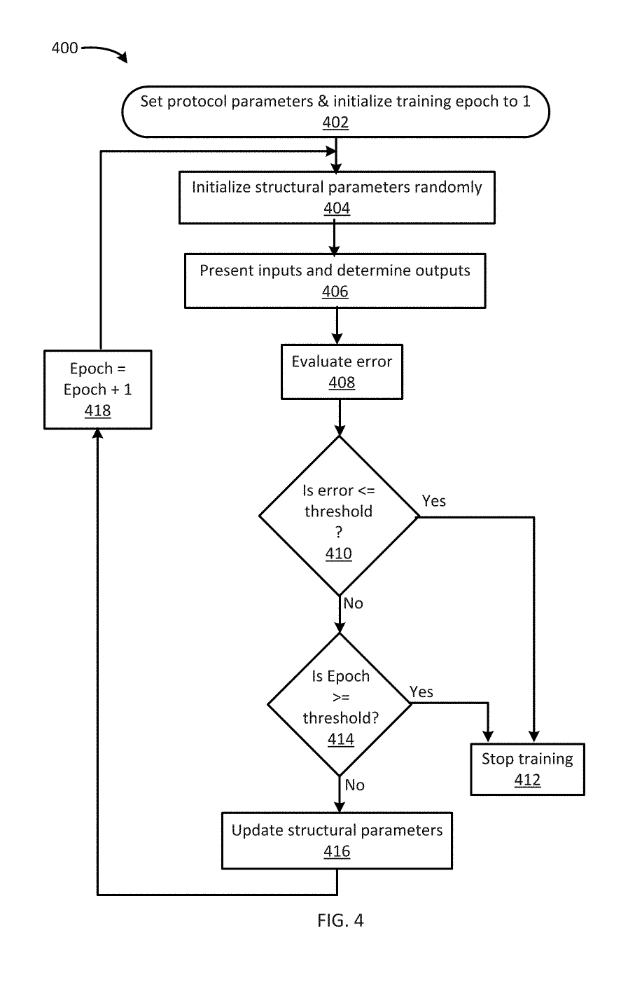

FIG. 4 is an example flowchart 400 of machine learning operations consistent with several embodiments of the present disclosure. In particular, flowchart 400 illustrates training a second order neuron. The operations of flowchart 400 may be performed by, for example, second order neuron 100 of FIG. 1, second order neuron 200 of FIG. 2, and/or system 400 (e.g., device 402 and/or ANN 404) of FIG. 4.

Operations of flowchart 400 may begin with setting protocol parameters and initializing a training epoch to 1 at operation 402. Structural parameters may be initialized randomly at operation 404. Structural parameters may include, but are not limited to, weights (e.g., weight elements in a weight matrix and/or a weight vector). Structural parameters may further include one or more bias values. Inputs may be presented and outputs may be determined at operation 406. For example, an input vector may be provided to a second order neuron and an output may be determined based, at least in part, on the input vector.

An error may be evaluated at operation 408. For example, an objective function may be evaluated to quantify an error between an actual output and a target output of the ANN. Whether the error is less than or equal to an error threshold may be determined at operation 410. If the error is less than the error threshold, then training may be stopped at 412. If the error is not less than or equal to the error threshold, then whether an epoch is greater than or equal to an epoch threshold may be determined at operation 414. If the epoch is greater than or equal to the epoch threshold, then training may stop at operation 412. If the epoch is not greater than or equal to the epoch threshold, then structural parameters may be updated at operation 416. The epoch may then be incremented at operation 418. The program flow may proceed to initializing structural parameters randomly at operation 404.

Thus, a neural network that includes a second order artificial neuron may be trained.

### Examples

FIGS. 5 through 8 are plots illustrating a functional value at each point in an input domain for a two input example second order neuron configured to implement XOR logic, an XOR-like function, a NOR-like function and a concentric ring classifier, respectively. The plots are configured to illustrate training a two-input example second order neuron, e.g., the example 2^{nd} order neuron 200 of FIG. 2. In the plots, a color map “cool” in MATLAB® was utilized to represent functional value at each point in an input domain. In the plots, “o” corresponds to 0 and “+” corresponds to 1. The training process refined a contour to separate labeled points to maximize classification accuracy. As illustrated in the plots, the contour can be two lines or quadric lines including parabolic and elliptical curves.

FIG. 5 is a plot 500 illustrating XOR logic implemented by the example second order neuron. For training, the initial parameters (i.e., weights) may be randomly selected in a framework of evolutionary computation. For example, the initial seed were randomly set to wᵣ=[−0.4, −0.4], w_{g}=[0.2, 1], w_{b}=[0, 0], b₁=−0.9095, b₂=−0.6426, c=0. Plot 500 includes a color map after a first iteration (N=1) 502, after 50 iterations 504, after 100 iterations 506 and after 180 iterations 508. After the training, the outputs for [0, 0], [0, 1], [1, 0] and [1, 1] are 0.4509, 0.5595, 0.5346 and 0.3111, respectively. It may be appreciated that the XOR logic outputs for [0, 0], [0, 1], [1, 0] and [1, 1] are 0, 1, 1, 0, respectively.

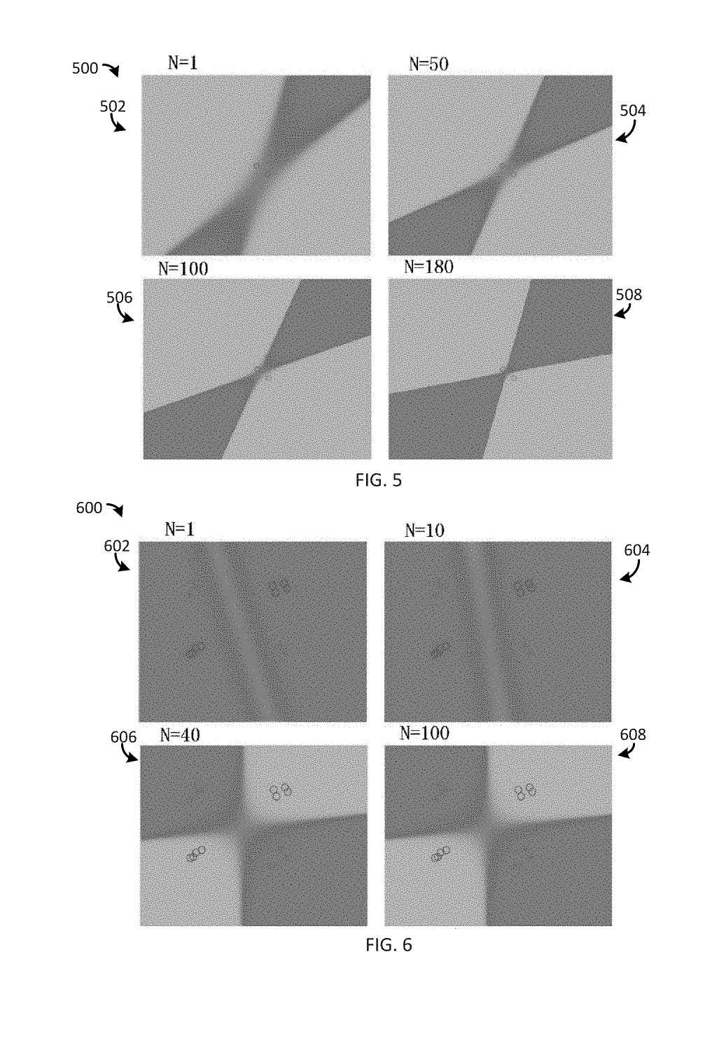

FIG. 6 is a plot 600 illustrating an XOR-like function (i.e., pattern) implemented by the example second order neuron. In this example, the initial seed were randomly set to wᵣ=[0.07994, −0.2119], w_{g}=[0.06049, −0.144], w_{b}=[0, 0], b₁=−0.9095, b₂=−0.6426, c=0. Plot 600 includes a color map after a first iteration (N=1) 602, after 10 iterations 604, after 40 iterations 606 and after 100 iterations 608.

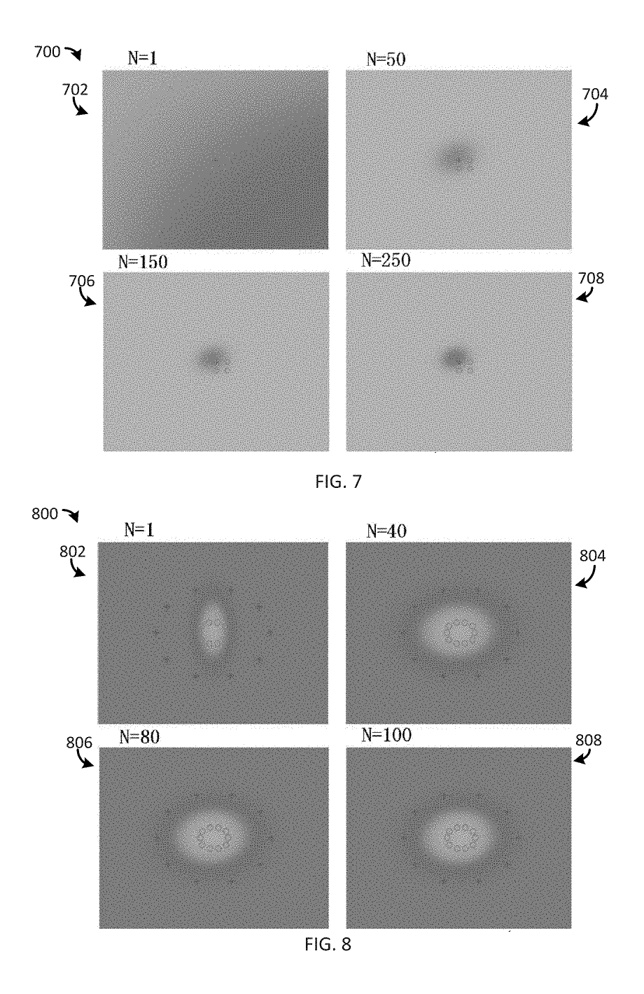

FIG. 7 is a plot 700 illustrating an NOR-like function (i.e., pattern) implemented by the example second order neuron. Plot 700 includes a color map after a first iteration (N=1) 702, after 50 iterations 704, after 150 iterations 706 and after 100 iterations 708.

FIG. 8 is a plot 800 illustrating classification of concentric rings with the example second order neuron. Two concentric rings were generated and were respectably assigned to two classes. In this example, the initial parameters were set to wᵣ=[0.12, 0.03], w_{g}=[0.09, −0.03], w_{b=}[0, 0.12], b₁=0.1, b₂=0.2, c=1.3. Plot 800 includes a color map after a first iteration (N=1) 802, after 40 iterations 804, after 80 iterations 806 and after 100 iterations 808.

Generally, the present disclosure relates to a second order neuron for machine learning. The second order neuron is configured to implement a second order function of an input vector. Generally, the second order neuron may be configured to determine a first dot product of an intermediate vector and an input vector. The intermediate vector may correspond to a product of the input vector and a first weight vector or a product of the input vector and a weight matrix. The second order neuron may be further configured to determine a second dot product of the input vector and a second weight vector containing n elements. The second order neuron may be further configured to determine an output of the second order neuron based, at least in part, on the first dot product and based, at least in part, on the second dot product. For example, an intermediate output may be input to a nonlinear function circuitry and an output of the nonlinear function circuitry may then correspond to the output of the second order neuron.

As used in any embodiment herein, the term “logic” may refer to an app, software, firmware and/or circuitry configured to perform any of the aforementioned operations. Software may be embodied as a software package, code, instructions, instruction sets and/or data recorded on non-transitory computer readable storage medium. Firmware may be embodied as code, instructions or instruction sets and/or data that are hard-coded (e.g., nonvolatile) in memory devices.

“Circuitry”, as used in any embodiment herein, may include, for example, singly or in any combination, hardwired circuitry, programmable circuitry such as computer processors including one or more individual instruction processing cores, state machine circuitry, and/or firmware that stores instructions executed by programmable circuitry. The logic may, collectively or individually, be embodied as circuitry that forms part of a larger system, for example, an integrated circuit (IC), an application-specific integrated circuit (ASIC), a field-programmable gate array (FPGA), a programmable logic device (PLD), a complex programmable logic device (CPLD), a system on-chip (SoC), etc.

Processor circuitry 312 may include, but is not limited to, a single core processing unit, a multicore processor, a graphics processing unit, a microcontroller, an application-specific integrated circuit (ASIC), a field programmable gate array (FPGA), a programmable logic device (PLD), etc.

Memory circuitry 314 may include one or more of the following types of memory: semiconductor firmware memory, programmable memory, non-volatile memory, read only memory, electrically programmable memory, random access memory, flash memory, magnetic disk memory, and/or optical disk memory. Either additionally or alternatively memory circuitry 414 may include other and/or later-developed types of computer-readable memory.

Embodiments of the operations described herein may be implemented in a computer-readable storage device having stored thereon instructions that when executed by one or more processors perform the methods. The processor may include, for example, a processing unit and/or programmable circuitry. The storage device may include a machine readable storage device including any type of tangible, non-transitory storage device, for example, any type of disk including floppy disks, optical disks, compact disk read-only memories (CD-ROMs), compact disk rewritables (CD-RWs), and magneto-optical disks, semiconductor devices such as read-only memories (ROMs), random access memories (RAMs) such as dynamic and static RAMs, erasable programmable read-only memories (EPROMs), electrically erasable programmable read-only memories (EEPROMs), flash memories, magnetic or optical cards, or any type of storage devices suitable for storing electronic instructions.

What is claimed is:

1. An apparatus comprising:
a second order neuron comprising:
a first dot product circuitry configured to determine a first dot product of an intermediate vector and an input vector, the intermediate vector corresponding to a product of the input vector and a first weight vector or the input vector and a weight matrix; and
a second dot product circuitry configured to determine a second dot product of the input vector and a second weight vector,
the input vector, the intermediate vector, the first weight vector and the second weight vector each containing a number, n, elements.

2. The apparatus of claim 1, wherein the second order neuron further comprises a nonlinear circuitry configured to determine the output of the second order artificial neuron based, at least in part, on the first dot product and based, at least in part, on the second dot product.

3. The apparatus of claim 1, wherein each element of the intermediate vector corresponds to a product of a respective weight of the first weight vector and a respective element of the input vector.

4. The apparatus of claim 1, wherein the intermediate vector corresponds to the product of the weight matrix and the input vector, the weight matrix having dimension n×n.

5. The apparatus of claim 3, wherein the second order neuron further comprises:
a third dot product circuitry configured to determine a third dot product of the input vector and a third weight vector, the third weight vector containing the number, n, elements;
a multiplier circuitry configured to multiply the second dot product and the third dot product to yield an intermediate product; and
a summer circuitry configured to add the intermediate product and the first dot product to yield an intermediate output, the output of the second order neuron related to the intermediate output.

6. The apparatus of claim 4, wherein the second order neuron further comprises a summer circuitry configured to add the first dot product and the second dot product to yield an intermediate output, the output of the second order neuron related to the intermediate output.

7. The apparatus of claim 1, wherein the n is equal to two and the second order neuron is configured to implement an exclusive or (XOR) function or a NOR gate.

8. The apparatus of claim 1, wherein the second order neuron is configured to classify a plurality of concentric circles.

9. The apparatus of claim 1, wherein each weight is determined by training.

10. The apparatus of claim 2, wherein the nonlinear circuitry is configured to implement a sigmoid function.

11. A system comprising:
a device comprising a processor circuitry, a memory circuitry and an artificial neural network (ANN) management circuitry; and
an ANN comprising a second order neuron, the device configured to provide an input vector to the ANN,
the second order neuron comprising a first dot product circuitry configured to determine a first dot product of an intermediate vector and the input vector, the intermediate vector corresponding to a product of the input vector and a first weight vector or the input vector and a weight matrix, and a second dot product circuitry configured to determine a second dot product of the input vector and a second weight vector, the input vector, the intermediate vector, the first weight vector and the second weight vector each containing a number, n, elements.

12. The system of claim 11, wherein the second order neuron further comprises a nonlinear circuitry configured to determine the output of the second order artificial neuron based, at least in part, on the first dot product and based, at least in part, on the second dot product.

13. The system of claim 11, wherein each element of the intermediate vector corresponds to a product of a respective weight of the first weight vector and a respective element of the input vector.

14. The system of claim 11, wherein the intermediate vector corresponds to the product of the weight matrix and the input vector, the weight matrix having dimension n×n.

15. The system of claim 13, wherein the second order neuron further comprises:
a third dot product circuitry configured to determine a third dot product of the input vector and a third weight vector, the third weight vector containing the number, n, elements;
a multiplier circuitry configured to multiply the second dot product and the third dot product to yield an intermediate product; and
a summer circuitry configured to add the intermediate product and the first dot product to yield an intermediate output, the output of the second order neuron related to the intermediate output.

16. The system of claim 14, wherein the second order neuron further comprises a summer circuitry configured to add the first dot product and the second dot product to yield an intermediate output, the output of the second order neuron related to the intermediate output.

17. The system of claim 11, wherein the n is equal to two and the second order neuron is configured to implement an exclusive or (XOR) function or a NOR gate.

18. The system of claim 11, wherein the second order neuron is configured to classify a plurality of concentric circles.

19. The system of claim 11, further comprising training circuitry configured to determine each weight.

20. The system of claim 12, wherein the nonlinear circuitry is configured to implement a sigmoid function.
